(19) United States
(12) Patent Application Publication
(10) Pub. No.: US 2026/0176764 A1
(43) Pub. Date: Jun. 25, 2026

(54) PLASMA PROBE DEVICE AND PLASMA PROCESSING APPARATUS

(71) Applicant: Tokyo Electron Limited, Tokyo (JP)

(72) Inventors: Yuji SAWADA, Nirasaki City (JP); Mitsutoshi ASHIDA, Nirasaki City (JP); Kenta KATO, Nirasaki City (JP)

(21) Appl. No.: 19/424,742

(22) Filed: Dec. 18, 2025

(30) Foreign Application Priority Data
Dec. 25, 2024 (JP) 2024-229261

(51) Int. Cl. C23C 16/509; G01R 19/00

(52) U.S. Cl. CPC C23C 16/509; G01R 19/0061

(57) ABSTRACT

A plasma probe device, which is provided in a member exposed to an internal space of a processing container in which plasma is generated, includes a probe cover including a tubular metal cover and a tubular insulating cover provided inside the tubular metal cover, a rod-shaped probe body provided inside the tubular insulating cover, and a metal plate connected to a tip end of the rod-shaped probe body and configured to cover a tip end of the probe cover. A discharge port, through which a gas is supplied to a space between the metal plate and the tip end of the probe cover, is provided near the rod-shaped probe body rather than a peripheral edge of the probe cover.

### CROSS-REFERENCE TO RELATED APPLICATION

This application is based upon and claims the benefit of priority from Japanese Patent Application No. 2024-229261, filed on Dec. 25, 2024, the entire contents of which are incorporated herein by reference.

### TECHNICAL FIELD

The present disclosure relates to a plasma probe device and a plasma processing apparatus.

### BACKGROUND

Patent Document 1 discloses a plasma probe device that senses plasma generated in a plasma generation space. The plasma probe device disclosed in Patent Document 1 includes an antenna part provided in an opening portion formed in a sidewall of a processing container an O-ring with an O-ring interposed. The antenna part is provided at a tip end of the plasma probe device. A tip end of the antenna part is a disk-shaped member and is arranged to close an opening of the opening portion via the O-ring. A surface of the tip end of the antenna part and a back surface near the opening portion in the sidewall of the processing container are spaced apart from each other so that a gap of a predetermined width is formed therebetween. A region extending from the opening portion to the O-ring, which corresponds to the surface of the tip end of the antenna part, is covered with an insulating film. A region extending from at least a side surface of the opening portion to the O-ring via a rear surface of the opening portion, which corresponds to a wall surface of the processing container, is also covered with the insulating film.

### PRIOR ART DOCUMENTS

### Patent Documents

Patent Document 1: Japanese Laid-Open Patent Publication No. 2019-046787

### SUMMARY

According to one embodiment of the present disclosure, a plasma probe device provided in a member exposed to an internal space of a processing container in which plasma is generated, the plasma probe device including: a probe cover including a tubular metal cover and a tubular insulating cover provided inside the tubular metal cover; a rod-shaped probe body provided inside the tubular insulating cover; and a metal plate connected to a tip end of the rod-shaped probe body and configured to cover a tip end of the probe cover, wherein a discharge port through which a gas is supplied to a space between the metal plate and the tip end of the probe cover is provided near the rod-shaped probe body rather than a peripheral edge of the probe cover.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional view schematically illustrating a configuration of a plasma processing apparatus provided with a plasma probe device according to an embodiment.

FIG. 2 is a cross-sectional view schematically illustrating a configuration of the plasma probe device.

FIG. 3 is a partial enlarged view of FIG. 2.

FIG. 4 is a cross-sectional view schematically illustrating a configuration of a plasma probe device for explaining another example of a gas discharge port.

FIG. 5 is a partial enlarged view of FIG. 4.

### DETAILED DESCRIPTION

Hereinafter, a plasma probe device according to an embodiment will be described with reference to the attached drawings. In the specification and the drawings, elements having substantially the same functional configuration will be designated by like reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Plasma Processing Apparatus

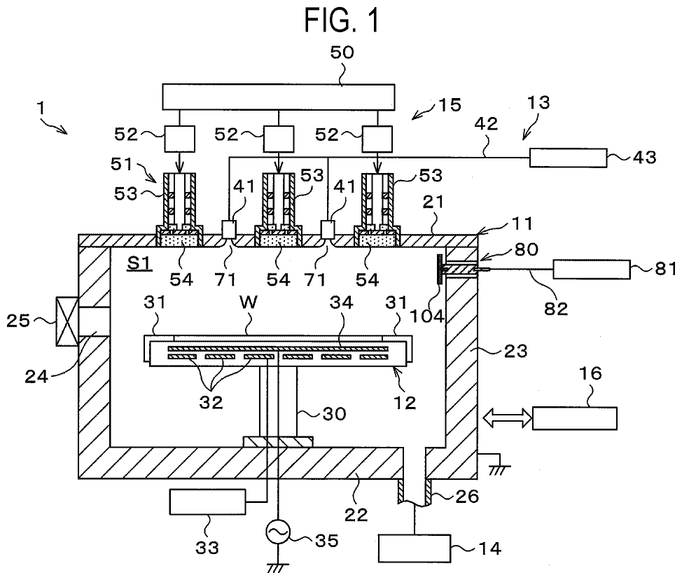

FIG. 1 is a longitudinal cross-sectional view schematically illustrating a configuration of a plasma processing apparatus provided with a plasma probe device according to an embodiment.

A plasma processing apparatus 1 of FIG. 1 includes a processing container 11 that accommodates a wafer W to perform plasma processing, a stage 12 disposed in an interior of the processing container 11 to place the wafer W thereon, a gas supply mechanism 13 that supplies a gas to the interior of the processing container 11, an exhaust device 14 that exhausts the interior of the processing container 11, a microwave introduction device 15 that generates microwaves for plasma generation in the interior of the processing container 11 and introduces the microwaves to the interior of the processing container 11, and a controller 16. The processing container 11 is grounded.

The processing container 11 is made of, for example, a metallic material such as aluminum and an alloy thereof, and has a substantially cylindrical shape. The processing container 11 includes a plate-shaped ceiling plate part 21 and a bottom portion 22, and a sidewall 23 connecting the ceiling plate part 21 and the bottom portion 22. The microwave introduction device 15 is provided above the processing container 11 and functions as a plasma generation means for generating plasma by introducing electromagnetic waves (microwaves) to the interior of the processing container 101.

The ceiling plate part 21 has a plurality of openings into which microwave radiation mechanisms 53 and gas introduction nozzles 41, which will be described later, of the microwave introduction device 15 are inserted. The sidewall 23 has a loading/unloading port 24 for loading/unloading the wafer W, which is a substrate to be processed, to/from a transfer chamber (not shown) adjacent to the processing container 11. The loading/unloading port 24 is opened and closed by a gate valve 25. The bottom portion 22 is provided with the exhaust device 14. The exhaust device 14 is connected to an exhaust pipe 26 provided at the bottom portion 22. The exhaust device 14 includes a vacuum pump (not shown). The interior of the processing container 11 is exhausted via the exhaust pipe 26 by this vacuum pump. An internal pressure of the processing container 11 is controlled by a pressure control valve (not shown) included in the exhaust device 14.

The stage 12 has a disk shape and is made of a ceramic such as AlN. The stage 12 is supported by a cylindrical support member 30 made of a ceramic such as AlN, which extends upward from the center of the bottom portion of the processing container 11. A guide ring 31 for guiding the wafer W is provided on an outer edge portion of the stage 12. Lift pins (not shown) for raising and lowering the wafer W are provided inside the stage 12 so as to move upward and downward with respect to an upper surface of the stage 12. A heater 32 is embedded in the stage 12. The heater 32 heats the wafer W placed on the stage 12 by power fed from a heater power supply 33.

A thermocouple (not shown) is inserted into the stage 12. The wafer W may be heated to a desired temperature based on a signal from the thermocouple. An electrode 34 having approximately the same size as the wafer W is buried above the heater 32 inside the stage 12. A radio-frequency power supply 35 is electrically connected to the electrode 34. A radio-frequency bias for ion attraction is applied to the stage 12 from the radio-frequency power supply 35. The radio-frequency power supply 35 may be omitted according to characteristics of plasma processing. In this example, the radio-frequency bias for ion attraction has been described as one example, but a DC (Direct Current) bias may be applied by connecting a DC power supply. Further, the radio-frequency bias may be omitted according to the characteristics of the plasma processing.

The gas supply mechanism 13 serves to introduce gas such as a plasma generation gas into the processing container 101 and includes the plurality of gas introduction nozzles 41. The gas introduction nozzles 41 are provided in the ceiling plate part 21 of the processing container 11. Each of the gas introduction nozzles 41 is connected to a gas source 43 via a gas supply pipe 42. Gas supplied from the gas source 43 is, for example, the plasma generation gas such as an Ar gas, or a film-formation raw material gas.

As described above, the microwave introduction device 15 is provided above the processing container 11 and functions as a plasma generation means that introduces the electromagnetic waves (microwaves) into the processing container 11 to generate plasma. The microwave introduction device 15 includes the ceiling plate part 21 of the processing container 11, which functions as a ceiling plate, a microwave outputter 50 that generates the microwaves, distributes and outputs the same to a plurality of paths, and an antenna unit 51 that introduces the microwaves output from the microwave outputter 50 into the processing container 11.

The microwave outputter 50 includes a microwave power supply, a microwave oscillator, an amplifier that amplifies microwaves oscillated by the microwave oscillator, and a distributor that distributes the microwaves amplified by the amplifier to a plurality of paths, which are not illustrated. The microwave oscillator oscillates the microwaves (for example, PLL oscillation) at, for example, 860 MHz. The frequency of the microwaves is not limited to 860 MHz, but may be in a range of 700 MHz to 10 GHz such as 2.45 GHz, 8.35 GHz, 5.8 GHz, and 1.98 GHz.

The antenna unit 51 includes a plurality of antenna modules (not shown). Each of the antenna modules includes an amplifier 52 that amplifies and outputs the microwaves from the microwave outputter 50, and the microwave radiation mechanisms 53 that radiate the microwaves output from the amplifier 52 into the processing container 11.

Each of the microwave radiation mechanisms 53 is provided in the ceiling plate part 21 and includes a microwave transmission plate 54 exposed to the interior of the processing container 11. The microwave transmission plate 54 is composed of a dielectric and has a shape (for example, a disk shape) that can efficiently radiate the microwaves in TE mode. The microwave radiation mechanisms 53 are arranged, for example, at the center of the ceiling plate part 21 and at six locations around the ceiling plate part 21 at equal intervals. As a material constituting the microwave transmission plate 54, for example, quartz, a ceramic, a fluorine-based resin such as polytetrafluoroethylene resin, or a polyimide resin may be used.

The plurality of gas introduction nozzles 41 of the gas supply mechanism 13 is arranged so as to surround the microwave transmission plate 54 (central microwave transmission plate) positioned at the center. More specifically, in the embodiment, for example, twelve gas introduction nozzles 41 are provided in the ceiling plate part 21 so as to surround the central microwave transmission plate 54 at equal intervals.

Gas supply holes 71 are formed at tip ends of the gas introduction nozzles 41, respectively, to be opened into the processing container 11. Gas from the gas source 43 is supplied to the gas supply holes 71 via the gas supply pipe 42 and the gas introduction nozzles 41 and is discharged from the gas supply holes 71 into the processing container 11.

Further, the plasma processing apparatus 1 includes a plasma probe device 80 provided in the sidewall 23 of the processing container 11. The plasma probe device 80 senses plasma generated in a plasma generation space S1 above the stage 12 in the interior of the processing container 11. Based on a sensing result, the plasma probe device 80 may calculate, for example, a plasma electron temperature or plasma electron density.

The plasma probe device 80 is connected to a monitor device 81 located outside the processing container 11 via a coaxial cable 82. The monitor device 81 includes a signal oscillator and outputs a signal of a predetermined frequency oscillated by the signal oscillator. This signal is transmitted to the plasma probe device 80 via the coaxial cable 82 and is delivered from a shield disk 104 at a tip end of the plasma probe device 80 to the plasma in the interior of the processing container 11. The plasma probe device 80 detects a current value of a signal reflected from the side of the plasma with respect to the signal transmitted toward the plasma, and sends the detected current value to the monitor device 81. The detected current value is sent from the monitor device 81 to the controller 16 to be described later, and is analyzed (specifically, by FTT (frequency) analysis) by the controller 16. In this way, the plasma electron temperature or the plasma electron density is calculated.

In the plasma processing apparatus 1 configured as described above, at least one controller 16 is provided. The controller 16 processes computer-executable instructions which cause the plasma processing apparatus 1 to execute various processes described in the present disclosure. The controller 16 may be configured to control individual constituent elements of the plasma processing apparatus 1 so as to execute the various processes described herein. In one embodiment, a part or the entirety of the controller 16 may be included in the plasma processing apparatus 1. The controller 16 may include a processor, a storage, and a communication interface. The controller 16 is implemented by, for example, a computer. The processor may be configured to read, from the storage, a program which provides a logic or routine for enabling various control operations, and execute the read program to perform the various control operations. This program may be stored in the storage in advance or acquired via a medium when necessary. The acquired program is stored in the storage, read from the storage, and executed by the processor. The medium may be various computer-readable storage media or may be a communication line connected to the communication interface. The storage medium may be a transitory or non-transitory storage medium. The processor may be a CPU (Central Processing Unit) or may be one or more circuits. The storage may include a RAM (Random Access Memory), a ROM (Read Only Memory), an HDD (Hard Disk Drive), an SSD (Solid State Drive), or a combination thereof. The communication interface may communicate with the plasma processing apparatus 1 via a communication line such as a LAN (Local Area Network).

### Processing Example by Plasma Processing Apparatus 1

An example of processing performed using the plasma processing apparatus 1 will be described.

First, the wafer W, which is supported by a transfer arm of a transfer mechanism provided outside the plasma processing apparatus 1, is loaded into the processing container 11 via the loading/unloading port 24 opened by the gate valve 25. Thereafter, the wafer W is delivered from the transfer arm to the lift pins and is placed on the stage 12 via the lift pins. After the wafer W is delivered from the transfer arm to the lift pins, the transfer arm is retracted from the processing container 11, and the loading/unloading port 24 is closed. Subsequently, the interior of the processing container 11 is depressurized to a predetermined vacuum level.

Thereafter, the plasma processing is performed on the wafer W. Specifically, a plasma generation gas and the like are supplied from the gas supply holes 71 into the processing container 11. In addition, microwaves are output from the microwave outputter 50. The output microwaves propagate, through the microwave radiation mechanisms 53, to a surface of the ceiling plate part 21 of the processing container 11 on the side of the plasma generation space S1. By an electric field of the microwaves propagating as surface waves, surface wave plasma is generated in a region immediately below the ceiling plate part 21. The plasma processing by such a surface wave plasma is performed on the wafer W.

### Plasma Probe Device 80

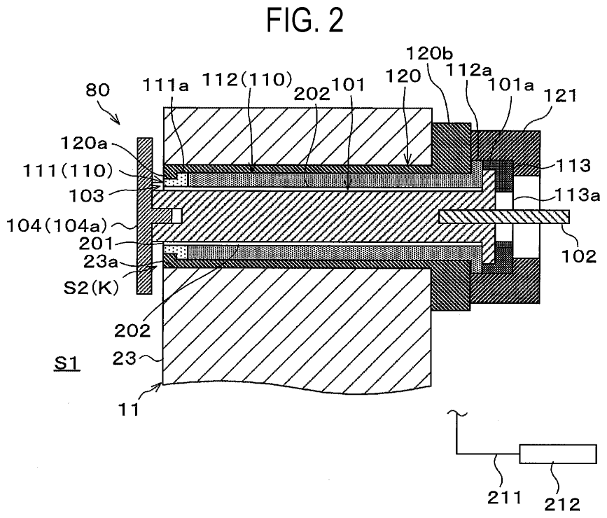

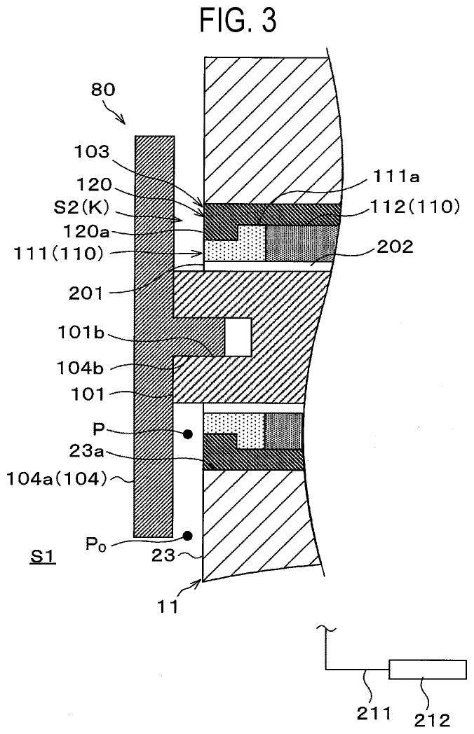

FIG. 2 is a cross-sectional view schematically illustrating a configuration of the plasma probe device 80. FIG. 3 is a partial enlarged view of FIG. 2.

In this embodiment, the plasma probe device 80 is provided in the sidewall 23 of the processing container 11. Specifically, as shown in FIGS. 2 and 3, the plasma probe device 80 is inserted through a through-hole 23a penetrating the sidewall 23. The plasma probe device 80 includes a probe body 101, an electrode 102, a probe cover 103, and a shield disk 104 which is a metal plate.

The probe body 101 is a rod-shaped member. Specifically, the probe body 101 is a member made of a metallic material, that is, a conductive material, and formed in a circular cross-sectional shape when viewed in an axial direction, that is, a cylindrical shape. The “axial direction” used herein refers to a direction in which the plasma probe device 80 or the probe body 101 extends, which is a left-right direction in the drawing. When the probe body 101 is formed in the cylindrical shape, a diameter of the probe body 101 is, for example, 5 to 10 mm. The plasma probe device 80 is provided so that the probe body 101 penetrates the sidewall 23 of the processing container 11. A flange 101a is provided on an outer periphery of a base end portion of the probe body 101. The flange 101a is used to fix the probe body 101 and the probe cover 103, which will be described later.

The electrode 102 transmits the signal from the monitor device 81 to the probe body 101. When the signal from the monitor device 81 is transmitted, the monitor device 81 detects a current flowing through the shield disk 104 and the probe body 101 to the plasma in the interior of the processing container 11. The electrode 102 is connected to, for example, the base end portion of the probe body 101.

The probe cover 103 covers the probe body 101 so as to electrically insulate the probe body 101 from the sidewall 23 of the processing container 11. The probe cover 103 includes an insulating cover 110 and a metal cover 120.

The insulating cover 110 is a member made of an electrical insulating material and formed in a tubular shape (specifically, for example, a cylindrical shape). The probe body 101 is provided inside the insulating cover 110. The insulating cover 110 includes a first insulating cover 111 and a second insulating cover 112.

The first insulating cover 111 is a member made of an electrical insulating material with a relatively high heat resistance (specifically, for example, a ceramic such as alumina) and formed in a tubular shape (specifically, for example, a cylindrical shape). When the first insulating cover 111 is formed in the cylindrical shape, an outer diameter of a tip end of the insulating cover 110 is, for example, 8 to 12 mm. The first insulating cover 111 covers a tip end portion of the probe body 101. A tip end surface of the first insulating cover 111 is exposed toward the plasma generation space S1 of the processing container 11. For example, the tip end surface of the first insulating cover 111 and a tip end surface of the metal cover 120 are aligned with each other without a step. The first insulating cover 111 includes a flange 111a on an outer periphery of a base end portion thereof.

The second insulating cover 112 is a member made of an electrical insulating material, which has a relatively low heat resistance but is unlikely to generate particles (specifically, for example, a fluorine resin) and formed in a tubular shape (specifically, for example, a cylindrical shape). The second insulating cover 112 covers the base end portion rather than a portion covered by the first insulating cover 111 in the probe body 101. A tip end surface of the second insulating cover 112 is in contact with a base end surface of the first insulating cover 111. The second insulating cover 112 includes a flange 112a on an outer periphery of the base end portion thereof.

The probe body 101 is fixed to the insulating cover 110 by inserting the flange 101a of the probe body 101 between a flange cover 113, which is provided on a base end side of the flange 112a, and the flange 112a. The flange cover 113 is made of, for example, from the same electrical insulating material as the second insulating cover 112 and formed in an annular shape having a hole 113a at the center thereof. At least one of the electrode 102 or the probe body 101 is inserted into the hole 113a.

The metal cover 120 is a member made of a metallic material having higher rigidity than that of the insulating cover 110 and formed in a tubular shape (specifically, for example, a cylindrical shape). When the metal cover 120 is formed in the cylindrical shape, an outer diameter of the metal cover 120 is 15 to 25 mm. The insulating cover 110 is provided inside the metal cover 120. For example, the metal cover 120 covers the entirety of the first insulating cover 111 and the entirety of the tip end portion of the second insulating cover 112 except for the flange 112a. A tip end surface of the metal cover 120 is exposed toward the plasma generation space S1 of the processing container 11. For example, the tip end surface of the metal cover 120 and an inner peripheral surface of the processing container 11 are aligned with each other without a step. The metal cover 120 includes an end portion 120a on an inner periphery of a tip end side and a flange 120b on an outer periphery of the base end portion thereof.

The insulating cover 110 is fixed to the metal cover 120 by inserting the first insulating cover 111, the second insulating cover 112, and the flange cover 113 between a base end cover 121, which is provided on a base end side of the flange 120b, and the end portion 120a. Further, by the insertion as described above, the flange 101a of the probe body 101 is inserted between the flange 112a of the second insulating cover 112 and the flange cover 113 so that the probe body 101 is fixed to the insulating cover 110. That is, by inserting the first insulating cover 111, the second insulating cover 112, and the flange cover 113 between the base end cover 121 and the end portion 120a, the probe body 101 is fixed to the probe cover 103 via the flange 101a.

The shield disk 104 is connected to a tip end of the probe body 101. In this example, the shield disk 104 is provided separately from the probe body 101. The shield disk 104 includes a circular disk portion 104a when viewed in the axial direction, and a convex portion 104b extending from a central portion of a surface on a base end side of the disk portion 104a toward the base end side. For example, the shield disk 104 is physically and electrically connected to the tip end of the probe body 101 by screwing a concave portion 101b provided at the tip end portion of the probe body 101 with the convex portion 104b.

In addition, the shield disk 104 covers the tip end of the probe cover 103. Specifically, the shield disk 104 is located in the plasma generation space S1 in a state in which the plasma probe device 80 is attached to the sidewall 23 of the processing container 11. To prevent electrical conduction between the shield disk 104 and the sidewall 23 of the processing container 11 via the probe cover 103, the shield disk 104 covers the tip end of the probe cover 103 with a gap K between the shield disk 104 and the tip end of the probe cover 103. The gap K is formed at least between a surface on the base end side (that is, a rear surface) of the shield disk 104 and the tip end surface of the metal cover 120. In this example, the gap K is also formed between the rear surface of the shield disk 104 and the tip end of the insulating cover 110 (specifically, the first insulating cover 111).

In this example, when viewed in the axial direction, the shield disk 104 is positioned such that an outer periphery thereof is located outside an outer periphery of the metal cover 120 (specifically, an outer periphery of the tip end of the metal cover 120). That is, a diameter of the disk portion 104a of the shield disk 104 is greater than an outer diameter of the tip end of the annular metal cover 120 and is, for example, 35 to 45 mm. Therefore, in this example, the disk portion 104a of the shield disk 104 covers the entirety of the tip end of the metal cover 120 and the tip end of the insulating cover 110 (specifically, the tip end of the first insulating cover 111).

When viewed in the axial direction, an outer periphery of the shield disk 104 is positioned outside the outer periphery of the above-described metal cover 120. Thus, the outer periphery of the shield disk 104 is located outside a peripheral edge of the through-hole 23a, which roughly coincides with an outer periphery of the metal cover 120. Therefore, in the state in which the shield disk 104 is attached, the plasma probe device 80 cannot be mounted in the sidewall 23 of the processing container 11. When mounting the plasma probe device 80 in the sidewall 23, the plasma probe device 80, to which the shield disk 104 is not attached, is inserted into the through-hole 23a of the sidewall 23 from the side of the first insulating cover 111, and then the shield disk 104 is attached to the tip end of the probe body 101.

Further, the plasma probe device 80 includes a gas discharge port 201 through which a gas is supplied to a space S2 formed by the gap K between the shield disk 104 and the tip end of the probe cover 103. When viewed in the axial direction, the gas discharge port 201 is located on the side of the probe body 101, that is, inward of the probe body 101, rather than a peripheral edge of the probe cover 103 (specifically, an outer peripheral edge of the tip end of the probe cover 103). The gas from the discharge port 201 may suppress conductive materials such as metals in a processing gas in the plasma generation space S1 from being deposited on the tip end of the insulating cover 110 and may suppress electrical conduction between the shield disk 104 or the probe body 101 and the sidewall 23 of the processing container 11 due to such deposits.

For example, when viewed in the axial direction, the discharge port 201 is formed in, for example, an annular shape so as to surround the periphery of the probe body 101. Alternatively, a plurality of discharge ports 201 may be provided in an annular shape along the periphery of the probe body 101 when viewed in the axial direction.

Further, the gas from the discharge port 201 is discharged in a radial shape centered on the probe body 101 in the space S2 when viewed in the axial direction. Specifically, the gas is discharged in the axial direction from the discharge port 201 located near the probe cover 103 toward the shield disk 104, collides with the surface of the base end of the shield disk 104, and then flows toward a peripheral edge of the shield disk 104. Accordingly, the gas from the discharge port 201 diffuses in the radial shape centered on the probe body 101 when viewed in the axial direction.

In this example, the discharge port 201 and a flow path 202 through which the gas is guided to the discharge port 201 are formed between the insulating cover 110 and the probe body 101. That is, the discharge port 201 and the flow path 202 are formed by an outer peripheral surface of the probe body 101 and an inner peripheral surface of the insulating cover 110. Specifically, the discharge port 201 is formed between the first insulating cover 111 and the probe body 101, and the flow path 202 is formed between the first insulating cover 111 and the second insulating cover 112, and the probe body 101.

The flow path 202 is connected to a gas source 212 via a flow path (not shown) formed inside the base end cover 121 and via a gas supply pipe 211. Gas supplied from the gas source 212 is supplied to the discharge port 201 via the gas supply pipe 211 or the flow path 202. After the gas is discharged from the discharge port 201, the gas flows in the space S2 formed by the gap K between the shield disk 104 and the probe cover 103, flows outward along the shield disk 104 when viewed in the axial direction, and is discharged to the plasma generation space S1 from the peripheral edge of the shield disk 104.

A ratio C/C₀ of a concentration C of the processing gas at an outermost peripheral position P of the insulating cover 110, when viewed in the axial direction, with respect to the space S2, to a concentration C₀ of a processing gas at an outermost peripheral position P₀ of the shield disk 104, when viewed in the axial direction, within the space S2, is represented by the Equation below:

$$C / {C}_{0} = exp ( - uL / D )$$

Here, u is a flow velocity (m/s) of the gas from the discharge port 201, L is a distance (m) from the outermost peripheral position P₀ to the outermost peripheral position P, and D is a diffusion coefficient (m²/s) of the gas from the discharge port 201, which depends on the type of gas.

When the Peclet number (uL/D) is 10 or greater, C/C₀ may be set to 0.001% or less. By lowering the concentration of the processing gas at the outermost peripheral position P of the insulating cover 110 when viewed in the axial direction, the deposition of the conductive materials such as metals in the processing gas on the tip end of the insulating cover 110 may be further suppressed.

Therefore, the probe cover 103, the probe body 101, the shield disk 104, and the discharge port 201 may be provided (that is, designed) so that the Peclet number in the outermost peripheral portion in the space S2 when viewed in the axial direction is 10 or greater. Specifically, both the design of the probe cover 103, the probe body 101, the shield disk 104, and the discharge port 201, and the setting of the flow velocity of the gas from the discharge port 201 may be performed so that the Peclet number in the outermost peripheral portion in the space S2 when viewed in the axial direction is 10 or greater.

In a case in which the flow velocity of the gas from the discharge port 201 needs to be set in a predetermined range in consideration of a device performance or the like, the following may be considered. That is, when the flow velocity of the gas from the discharge port 201 falls within the predetermined range, the probe cover 103, the probe body 101, the shield disk 104, and the discharge port 201 may be provided so that the Peclet number at the outermost peripheral portion in the space S2 when viewed in the axial direction is 10 or greater.

The plasma probe device 80 configured as described above senses plasma in the plasma generation space S1 while the plasma processing is being performed on the wafer W by, for example, the plasma processing apparatus 1. While the plasma processing is being performed on the wafer W by the plasma processing apparatus 1, the gas is discharged from the discharge port 201 of the plasma probe device 80 regardless of whether or not plasma characteristics are being measured using the plasma probe device 80.

### Main Effects of Present Embodiment

As described above, in this embodiment, the plasma probe device 80 is provided with the probe cover 103 including the tubular metal cover 120 and the tubular insulating cover 110 provided inside the metal cover 120, and the rod-shaped probe body 101 provided inside the insulating cover 110. The plasma probe device 80 further includes the shield disk 104, which is connected to the tip end of the probe body 101 and covers the tip end of the probe cover 103. This makes it possible to suppress the tip end of the probe cover 103 including the insulating cover 110 from being exposed to conductive materials (for example, metals) contained in the processing gas in the plasma generation space S1. In addition, the plasma probe device 80 includes the gas discharge port 201, which supplies the gas to the space S2 between the shield disk 104 and the tip end of the probe cover 103, and disposed to be closer to the probe body 101, that is, inward of the probe body 101, than the peripheral edge (outer peripheral edge) of the probe cover 103. Thus, the gas discharged from the discharge port 201 flows toward the peripheral edge of the shield disk 104 in the space S2, which makes it possible to suppress the processing gas in the plasma generation space S1 from flowing into the space S2 via, for example, the gap between the shield disk 104 and the inner peripheral surface of the sidewall 23 of the processing container 11. Therefore, it is possible to further suppress the tip end of the probe cover 103 including the insulating cover 110 from being exposed to the conductive materials contained in the processing gas. This makes it possible to suppress the conductive materials from being deposited on the tip end of the insulating cover 110, and suppress a current flowing through the probe body 101 from leaking to the sidewall 23 of the processing container 11 via such deposits. Accordingly, the plasma characteristics in the plasma generation space S1 may be accurately measured using the plasma probe device 80.

According to the embodiment, the gas from the discharge port 201 may suppress the gap between the shield disk 104 and the metal cover 120 and the gap between the shield disk 104 and the sidewall 23 of the processing container 11 from being buried with the conductive materials in the processing gas. This makes it possible to suppress the current flowing through the probe body 101 from leaking to the sidewall 23 of the processing container 11 via the materials buried into the gaps. Therefore, it is possible to accurately measure the plasma characteristics in the plasma generation space S1.

According to this embodiment, a surface area of a portion exposed to plasma and through which the current induced by the plasma flows, that is, a surface area of the shield disk 104, may be increased without enlarging the through-hole 23a into which the plasma probe device 80 is inserted and penetrates. Thus, an S/N (Signal-to-Noise) ratio of the current detected by the plasma probe device 80 may be improved. In addition, the enlargement of the through-hole 23a may cause an increase in size of the plasma probe device 80. This results in a degradation in mounting capability of the plasma probe device 80. In this embodiment, in order to improve the S/N ratio of the detected current, it is not necessary to enlarge the through-hole 23a as described above. Therefore, while maintaining the size and mounting capability of the plasma probe device 80, it is possible to improve the S/N ratio of the detected current induced by the plasma.

### Another Example of Gas Discharge Port

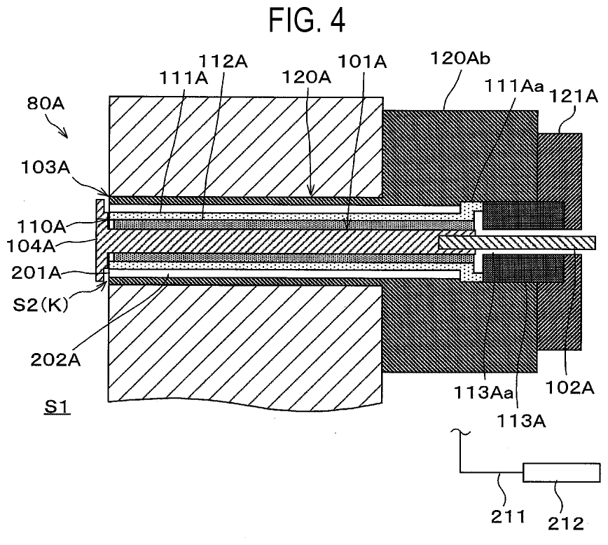

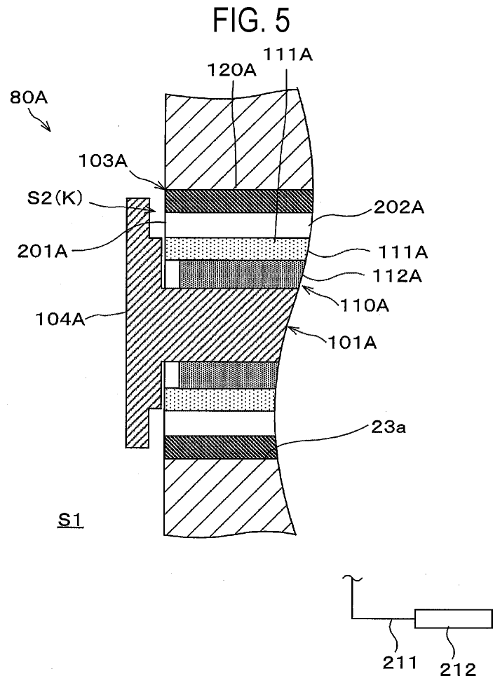

FIG. 4 is a cross-sectional view schematically illustrating a configuration of a plasma probe device for explaining another example of the gas discharge port. FIG. 5 is an enlarged partial view of FIG. 4.

In the plasma probe device 80 shown in FIG. 2 and the like, the gas discharge port 201 and the flow path 202 that guides the gas to the discharge port 201 are formed between the insulating cover 110 and the probe body 101. On the other hand, in a plasma probe device 80A shown in FIGS. 4 and 5, a gas discharge port 201A and a flow path 202A that guides the gas to the discharge port 201A are formed between an insulating cover 110A and a metal cover 120A. That is, the gas discharge port 201A and the flow path 202A that guides the gas to the gas discharge port 201A are formed by an outer peripheral surface of the insulating cover 110A (specifically, a first insulating cover 111A described later) and an inner peripheral surface of the metal cover 120A.

Hereinafter, the plasma probe device 80A will be described in more detail.

The plasma probe device 80A includes a probe body 101A, an electrode 102A, a probe cover 103A, and a shield disk 104A as a metal plate.

Like the above-described probe body 101, the probe body 101A is a rod-shaped member. When the probe body 101A is formed in a cylindrical shape, a diameter of the probe body 101A is, for example, 5 to 10 mm. The probe body 101A is fixed inside the probe cover 103A by, for example, fitting. Specifically, the probe body 101A is fixed inside the probe cover 103A by being fitted with a second insulating cover 112A described later.

A function of the electrode 102A is the same as that of the electrode 102.

Like the probe cover 103, the probe cover 103A covers the probe body 101A so as to electrically insulate the probe body 101A from the sidewall 23 of the processing container 11. The probe cover 103A includes an insulating cover 110A and a metal cover 120A.

The insulating cover 110A is a tubular member (specifically, for example, a cylindrical shape) made of an electrical insulating material. The probe body 101A is provided inside the insulating cover 110A. The insulating cover 110A includes the first insulating cover 111A and the second insulating cover 112A.

The first insulating cover 111A is a member made of an electrical insulating material with a relatively high heat resistance (specifically, for example, a ceramic such as alumina) and formed in a tubular shape (specifically, for example, a cylindrical shape). When the first insulating cover 111A is formed in the cylindrical shape, an outer diameter of a tip end of the first insulating cover 111A is, for example, 10 to 18 mm. The first insulating cover 111A covers substantially the entirety of the probe body 101A. Specifically, the first insulating cover 111A covers the entirety of the second insulating cover 112A that covers the probe body 101A. A tip end surface of the first insulating cover 111A is exposed to the plasma generation space S1 of the processing container 11. The first insulating cover 111A includes a flange 111Aa on an outer periphery of a base end portion thereof.

The second insulating cover 112A is a member made of an electrical insulating material which has a relatively low heat resistance but is unlikely to generate particles (specifically, for example, a fluorine resin) and formed in a tubular shape (specifically, for example, a cylindrical shape). When the second insulating cover 112A is formed in the cylindrical shape, an outer diameter of a tip end of the second insulating cover 112A is, for example, 8 to 16 mm. The second insulating cover 112A is provided inside the first insulating cover 111A and covers substantially the entirety of the probe body 101A. A tip end surface of the second insulating cover 112A is exposed to the plasma generation space S1 of the processing container 11. The second insulating cover 112A is fixed inside the first insulating cover 111A by being fitted with the first insulating cover 111A.

The metal cover 120A is a member made of a metallic material having higher rigidity than that of the insulating cover 110A and formed in a tubular shape (specifically, for example, a cylindrical shape). When the metal cover 120A is formed in the cylindrical shape, an outer diameter of the metal cover 120A is, for example, 15 to 25 mm. The insulating cover 110A is provided inside the metal cover 120A. For example, the metal cover 120A covers the entirety of the insulating cover 110A. A tip end surface of the metal cover 120A is exposed to the plasma generation space S1 of the processing container 11. The metal cover 120A includes a flange 120Ab on an outer periphery of a base end portion thereof.

The first insulating cover 111A is fixed to the metal cover 120A by sandwiching the flange 111Aa of the first insulating cover 111A and a flange cover 113A between a base end cover 121A, which is provided on a base end side of the flange 120Ab, and the flange 120Ab. The flange cover 113A is made of, for example, the same electrical insulating material as the second insulating cover 112A, and is formed in an annular shape having a hole 113Aa at the center thereof. At least one of the electrode 102A or the probe body 101A is inserted into the hole 113Aa.

The shield disk 104A is connected to a tip end of the probe body 101A. In this example, the shield disk 104A is provided integrally with the probe body 101A. Thus, the shield disk 104A is physically and electrically connected to the tip end of the probe body 101A. The shield disk 104A is formed in a circular disk shape when viewed in the axial direction.

In addition, the shield disk 104A covers a tip end of the probe cover 103A. Specifically, the shield disk 104A is located in the plasma generation space S1 in a state in which the plasma probe device 80A is attached to the sidewall 23 of the processing container 11. The shield disk 104A is provided with a gap K between the shield disk 104A and the tip end of the probe cover 103A to cover the tip end of the probe cover 103A.

In this example, when viewed in the axial direction, the shield disk 104A has an outer periphery located inward of an outer periphery of the metal cover 120A (specifically, an outer periphery of a tip end of the metal cover 120A) and outward of an inner periphery of the metal cover 120A (specifically, an inner periphery of the tip end of the metal cover 120A). That is, a diameter of the disk-shaped shield disk 104A is smaller than an outer diameter of the tip end of the annular metal cover 120A and is larger than an inner diameter of the tip end of the annular metal cover 120A. In other words, the diameter of the disk-shaped shield disk 104A is slightly smaller than the outer diameter of the tip end of the cylindrical metal cover 120A. Therefore, in this example, the shield disk 104A covers the entirety of a tip end of the insulating cover 110A and a portion of the tip end of the metal cover 120A.

When viewed in the axial direction, the outer periphery of the shield disk 104A is located inward of the outer periphery of the above-described metal cover 120A. Thus, the outer periphery of the shield disk 104A is located inward of a peripheral edge of the through-hole 23a, which substantially coincides with the outer periphery of the metal cover 120A. Accordingly, unlike the plasma probe device 80, the plasma probe device 80A may be mounted in the sidewall 23 of the processing container 11 in a state in which the shield disk 104A is provided.

In addition, the plasma probe device 80A includes a gas discharge port 201A through which a gas is supplied to the space S2 formed by the gap K between the shield disk 104A and the tip end of the probe cover 103A. When viewed in the axial direction, the gas discharge port 201A is located on the side closer to the probe body 101A, that is, on an inner side thereof, rather than a peripheral edge of the probe cover 103A (specifically, an outer peripheral edge of the tip end of the probe cover 103A).

The discharge port 201A is formed in, for example, an annular shape so as to surround the probe body 101A when viewed in the axial direction.

In this example, as described above, the discharge port 201A and the flow path 202A that guides the gas to the discharge port 201A are formed between the insulating cover 110A and the metal cover 120A.

The flow path 202A is connected to the gas source 212 via a flow path (not shown) formed inside the flange 120Ab and the gas supply pipe 211. Gas supplied from the gas source 212 is supplied to the discharge port 201A via the gas supply pipe 211 or the flow path 202A. After the gas is discharged from the discharge port 201A, the gas flows in the space S2 formed by the gap K between the shield disk 104A and the probe cover 103A, flows outward along the shield disk 104A when viewed in the axial direction, and is discharged to the plasma generation space S1 from the peripheral edge of the shield disk 104.

Even in the plasma probe device 80A of this example, by covering the tip end of the probe cover 103A with the shield disk 104A, the tip end of the probe cover 103A including the insulating cover 110A may be suppressed from being exposed to the conductive materials (for example, metals) contained in the processing gas in the plasma generation space S1. In addition, the gas discharged from the discharge port 201A may further suppress the tip end of the probe cover 103A including the insulating cover 110A from being exposed to the conductive materials contained in the processing gas. This makes it possible to suppress the conductive materials from being deposited on the tip end of the insulating cover 110A. Thus, it is possible to suppress the current flowing through the probe body 101A from leaking to the sidewall 23 of the processing container 11 via such a deposition. Accordingly, plasma characteristics in the plasma generation space S1 may be accurately measured using the plasma probe device 80A.

In addition, even in the plasma probe device 80A of this example, the gap between the shield disk 104A and the metal cover 120A may be suppressed from being buried with the conductive materials in the processing gas. Therefore, the current flowing through the probe body 101A is suppressed from leaking to the sidewall 23 of the processing container 11 via the materials buried into the gap. Accordingly, it is possible to accurately measure the plasma characteristics in the plasma generation space S1.

Further, unlike the plasma probe device 80, in the plasma probe device 80A, there is no need to separate the shield disk 104A when the plasma probe device 80A is attached to the sidewall 23 of the processing container. This improves the mounting capability. In addition, compared to the case in which the shield disk 104A is omitted in the plasma probe device 80A, a portion exposed to plasma and through which current induced by the plasma flows has a large surface area. Therefore, an S/N ratio of the current detected by the plasma probe device 80A may be improved. Thus, according to the plasma probe device 80A, both the mounting capability to the sidewall 23 of the processing container 11 and the S/N ratio of the detected current induced by the plasma may be improved.

Further, in the plasma probe device 80A, the diameter of the disk-shaped shield disk 104A is smaller than the outer diameter of the tip end of the annular metal cover 120A. Therefore, when the plasma probe device 80A is mounted in the sidewall 23 of the processing container 11, the shield disk 104A is less likely to collide with the through-hole 23a of the sidewall 23. As a result, damage to a root portion of the first insulating cover 111A due to such collision may be suppressed.

### Other Modifications

In the above example, the number of plasma probe devices provided in the processing container 11 is one. However, a plurality of plasma probe devices may be provided.

In the above example, the plasma probe device is provided in the sidewall 23 of the processing container 11. However, the plasma probe device may be provided in a member exposed to an internal space of the processing container 11, that is, a member exposed to the plasma, other than the sidewall 23 of the processing container 11. For example, the plasma probe device may be provided in the ceiling plate part 21 of the processing container 11 or may be provided in a peripheral edge portion of the stage 12. When the plasma probe device is provided in the peripheral edge portion of the stage 12, a part corresponding to the shield disk 104 or 104A is provided to be arranged above the stage 12.

According to the present disclosure in some embodiments, it is possible to accurately measure characteristics of plasma using a plasma probe device provided in a member exposed to an internal space of a processing container in which the plasma is generated.

It should be noted that the embodiments disclosed herein are exemplary in all respects and are not restrictive. The above-described embodiments may be omitted, replaced or modified in various forms without departing from the scope and spirit of the appended claims. For example, constituent elements of the above embodiments may be arbitrarily combined. From this arbitrary combination, it is needless to say that the operations and effects of the respective constituent elements related to the combination may be obtained, and other operations and other effects obvious to those skilled in the art may be obtained from the description of the present specification.

The effects described herein are illustrative or exemplary only and are not restrictive. That is, the technique of the present disclosure may obtain other effects obvious to those skilled in the art from the description herein in addition to or in place of the above effects.

The following configuration examples also belong to the technical scope of the present disclosure.

(1) A plasma probe device provided in a member exposed to an internal space of a processing container in which plasma is generated, the plasma probe device including:
a probe cover including a tubular metal cover and a tubular insulating cover provided inside the tubular metal cover;
a rod-shaped probe body provided inside the tubular insulating cover; and
a metal plate connected to a tip end of the rod-shaped probe body and configured to cover a tip end of the probe cover,
wherein a discharge port through which a gas is supplied to a space between the metal plate and the tip end of the probe cover is provided near the rod-shaped probe body rather than a peripheral edge of the probe cover.

(2) In the plasma probe device of (1) above, the rod-shaped probe body has a circular cross-sectional shape when viewed in an axial direction, and the discharge port is formed in an annular shape so as to surround the rod-shaped probe body in the axial direction.

(3) In the plasma probe device of (1) or (2) above, the gas is discharged from the discharge port so as to diffuse in a radial shape centered at the rod-shaped probe body in the internal space when viewed in an axial direction.

(4) In the plasma probe device of any one of (1) to (3) above, the discharge port and a flow path configured to guide the gas to the discharge port are formed between the tubular metal cover and the tubular insulating cover.

(5) In the plasma probe device of any one of (1) to (3) above, the discharge port and a flow path configured to guide the gas to the discharge port are formed between the tubular insulating cover and the rod-shaped probe body.

(6) In the plasma probe device of any one of (1) to (5) above, the probe cover, the rod-shaped probe body, the metal plate, and the discharge port are provided so that a Peclet number is 10 or greater at an outermost peripheral portion of the tubular insulating cover in the internal space when viewed in an axial direction.

(7) In the plasma probe device of any one of (1) to (6) above, an outermost periphery of the metal plate is located inward of an outermost periphery of the tubular metal cover and outward of an innermost periphery of the tubular metal cover.

(8) A plasma processing apparatus includes the plasma probe device of any one of (1) to (7) above.

What is claimed is:

1. A plasma probe device provided in a member exposed to an internal space of a processing container in which plasma is generated, the plasma probe device comprising:
a probe cover including a tubular metal cover and a tubular insulating cover provided inside the tubular metal cover;
a rod-shaped probe body provided inside the tubular insulating cover; and
a metal plate connected to a tip end of the rod-shaped probe body and configured to cover a tip end of the probe cover,
wherein a discharge port through which a gas is supplied to a space between the metal plate and the tip end of the probe cover is provided near the rod-shaped probe body rather than a peripheral edge of the probe cover.

2. The plasma probe device of claim 1, wherein the rod-shaped probe body has a circular cross-sectional shape when viewed in an axial direction, and
wherein the discharge port is formed in an annular shape so as to surround the rod-shaped probe body in the axial direction.

3. The plasma probe device of claim 1, wherein the gas is discharged from the discharge port so as to diffuse in a radial shape centered at the rod-shaped probe body in the internal space when viewed in an axial direction.

4. The plasma probe device of claim 1, wherein the discharge port and a flow path configured to guide the gas to the discharge port are formed between the tubular metal cover and the tubular insulating cover.

5. The plasma probe device of claim 1, wherein the discharge port and a flow path configured to guide the gas to the discharge port are formed between the tubular insulating cover and the rod-shaped probe body.

6. The plasma probe device of claim 1, wherein the probe cover, the rod-shaped probe body, the metal plate, and the discharge port are provided so that a Peclet number is 10 or greater at an outermost peripheral portion of the tubular insulating cover in the internal space when viewed in an axial direction.

7. The plasma probe device of claim 1, wherein an outermost periphery of the metal plate is located inward of an outermost periphery of the tubular metal cover and outward of an innermost periphery of the tubular metal cover.

8. A plasma processing apparatus including the plasma probe device of claim 1.
